(19) United States
(12) Patent Application Publication
(10) Pub. No.: US 2026/0188217 A1
(43) Pub. Date: Jul. 2, 2026

(54) SUBPIXEL AND DISPLAY DEVICE INCLUDING THE SAME

(71) Applicant: LG Display Co., Ltd., Seoul (KR)

(72) Inventor: Hanui NAM, Paju-si (KR)

(73) Assignee: LG Display Co., Ltd., Seoul (KR)

(21) Appl. No.: 19/238,191

(22) Filed: Jun. 13, 2025

(30) Foreign Application Priority Data
Dec. 30, 2024 (KR) 10-2024-0200453

(51) Int. Cl. G09G 3/3233; G09G 3/00; H10K 59/131

(52) U.S. Cl. CPC G09G 3/3233; G09G 3/035; H10K 59/131; G09G 2300/0819; G09G 2300/0852; G09G 2300/0861; G09G 2310/0251; G09G 2310/06; G09G 2310/08; G09G 2320/0233; G09G 2330/023

(57) ABSTRACT

A display device includes a display area and a non-display area. A first subpixel among a plurality of subpixels includes a light emitting element having a common electrode, an intermediate layer, and a pixel electrode; a driving transistor controlling a connection between a second node and a third node according to a signal input to a first node; a first driving voltage line and a second driving voltage line to which a driving voltage is input; a first emission control transistor connected between the second node and the first driving voltage line and controlled by a first emission control signal; and a first scan transistor connected between the second node and the second driving voltage line and controlled by a first scan signal. The driving voltage may be selectively input to the second node via the first emission control transistor or the first scan transistor based on respective control signals.

### CROSS-REFERENCE TO RELATED APPLICATION

This application claims priority from Korean Patent Application No. 10-2024-0200453, filed on Dec. 30, 2024, which is hereby incorporated by reference for all purposes as if fully set forth herein.

### BACKGROUND

### Technical Field

Embodiments of the disclosure relate to a subpixel and a display device including the same.

### Description of Related Art

As the information society develops, demand for display devices for displaying images is increasing in various forms. Various types of display devices, such as liquid crystal display devices and organic light emitting display devices, are being utilized in recent years.

### BRIEF SUMMARY

The present disclosure relates to a subpixel structure and display device configured to reduce or minimize voltage fluctuations at the driving transistor nodes by supplying a driving voltage to the drain or source node prior to the light emission period. By pre-charging these nodes through emission control or scan transistors, the subject matter described herein prevents unintended early light emission, thereby improving image quality and reducing power consumption. A shield pattern disposed beneath the drain and source nodes facilitates capacitive coupling, allowing controlled voltage stabilization at the pixel electrode. This arrangement enhances node initialization, stabilizes driving operations, and mitigates display artifacts such as unintended black screens.

The display device further includes a flexible multilayer substrate structure incorporating inorganic barrier layers to inhibit moisture penetration and minimize charge leakage, along with crack prevention patterns in bending areas to improve mechanical reliability. A touch sensor layer is disposed above the encapsulation layer, and touch routing lines are configured with multiple metal layers to optimize electrical resistance while reducing or minimizing interference with light emission. Additionally, a multi-phase gate driving scheme synchronizes scan signals, emission control signals, and data input to precisely control the timing of light emission, thereby enhancing operational stability, reducing power consumption, and improving the overall durability of the display panel.

Embodiments of the disclosure may provide a subpixel that reduces or minimizes voltage fluctuations at nodes of a driving transistor caused by capacitance and a display device including the same.

Embodiments of the disclosure may provide a subpixel that supplies a driving voltage to the drain node or the source node of a driving transistor before an emission period and a display device including the same.

Technical benefits of embodiments of the disclosure are not limited to those set forth herein, and other unmentioned benefits would be apparent to one of ordinary skill in the art from the following description.

Embodiments of the disclosure may provide a display device comprising a display area where a plurality of subpixels are positioned and an image is displayed, and a non-display area outside the display area, wherein a first subpixel among the plurality of subpixels includes: a light emitting element including a common electrode, an intermediate layer, and a pixel electrode, a driving transistor controlling a connection of a second node and a third node according to a signal input to a first node, a first driving voltage line and a second driving voltage line to which a driving voltage is input, a first emission control transistor connected between the second node and the first driving voltage line and controlled by a first emission control signal, and a first scan transistor connected between the second node and the second driving voltage line and controlled by a first scan signal, and wherein the driving voltage is input to the second node while the first emission control transistor is turned on according to the first emission control signal or the first scan transistor is turned on according to the first scan signal.

Embodiments of the disclosure may provide a display device comprising a substrate, a first insulation layer positioned on the substrate, a shield pattern positioned on the first insulation layer, a second insulation layer positioned on the first insulation layer, a third insulation layer positioned on the second insulation layer, a first electrode and a second electrode of a driving transistor positioned on the third insulation layer, a drain node positioned on the second insulation layer, contacting the first electrode, and overlapping the shield pattern, a source node positioned on the second insulation layer, contacting a second electrode contacting the shield pattern, and overlapping the shield pattern, and a light emitting element including a pixel electrode contacting the second electrode, an intermediate layer disposed on the pixel electrode, and a common electrode disposed on the intermediate layer, wherein as a voltage input to the drain node increases, a voltage of the source node increases and, as the voltage of the source node increases, a voltage of the pixel electrode increases, and wherein after a data voltage is applied to the source node, and before the intermediate layer emits light, a common voltage is applied to the drain node.

Embodiments of the disclosure may provide a subpixel comprising a light emitting element including a common electrode, an intermediate layer, and a pixel electrode, a driving transistor controlling a connection of a second node and a third node according to a signal input to a first node, a first driving voltage line and a second driving voltage line to which a driving voltage is input, a first emission control transistor connected between the second node and the first driving voltage line and controlled by a first emission control signal, and a first scan transistor connected between the second node and the second driving voltage line and controlled by a first scan signal, wherein after a data voltage is applied to the third node, and before the light emitting element emits light, the second node receives the driving voltage as the first scan transistor is turned on.

According to embodiments of the disclosure, there may be provided a subpixel and a display device including the same that prevent unintended light emission of a light emitting element by supplying a driving voltage to the drain node or the source node of a driving transistor before the light emitting element emits light.

According to embodiments of the disclosure, there may be provided a subpixel and a display device including the same that operate at low power by preventing unintended light emission.

The effects of the disclosure are not limited to the foregoing objects, and other effects will be apparent to one of ordinary skill in the art from the following detailed description.

### DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 is a view illustrating a configuration of a display device according to various embodiments of the disclosure;

FIG. 2 is a plan view illustrating a display device according to various embodiments of the disclosure;

FIG. 3 is a view illustrating an example of a cross-sectional structure of the display panel of FIG. 2 according to embodiments of the disclosure;

FIG. 4 is a cross-sectional view illustrating a driving transistor, taken along area A of FIG. 3, according to embodiments of the disclosure;

FIG. 5 is a view illustrating an equivalent circuit of a subpixel according to embodiments of the disclosure;

FIG. 6 is a view illustrating a connection relationship between a gate driving integrated circuit and a display area according to various embodiments of the disclosure;

FIG. 7 is a view illustrating a scan driver according to embodiments of the disclosure;

FIG. 8 is a view illustrating another scan driver according to embodiments of the disclosure;

FIG. 9 is a view illustrating an emission driver according to embodiments of the disclosure; and

FIG. 10 is a timing diagram of a subpixel according to embodiments of the disclosure.

FIG. 11 is a flow chart of a method of operating a display device.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

As used herein, “precharge” refers to an operation of supplying a voltage, such as a driving voltage, to a node, such as a second node of a driving transistor, after a data voltage has been written to another node, such as a third node, and before light emission from a light emitting element occurs. The precharge operation stabilizes the voltage of the second node to prepare the subpixel for subsequent emission, suppresses leakage current, and ensures accurate control of the driving transistor during the light emission period.

Hereinafter, various embodiments of the disclosure are described in detail with reference to the accompanying drawings.

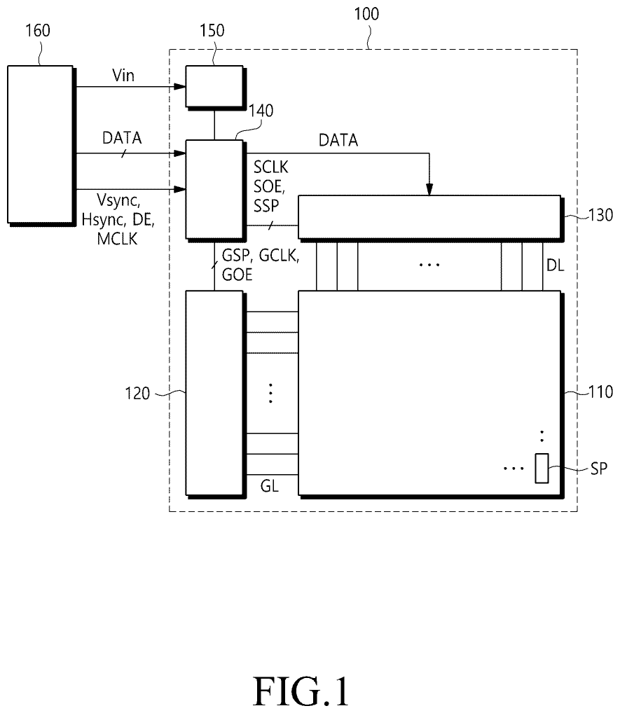

FIG. 1 is a view illustrating a configuration of a display device 100 according to embodiments of the disclosure.

Referring to FIG. 1, a display device 100 according to an embodiment of the disclosure may include a display panel 110 where a plurality of gate lines GL and data lines DL are connected, and a plurality of subpixels SP are arranged in a matrix form, a gate driving circuit 120 driving the plurality of gate lines GL, a data driving circuit 130 supplying a data voltage through the plurality of data lines DL, a controller 140 controlling the gate driving circuit 120 and the data driving circuit 130, and a power management circuit 150.

The display panel 110 displays an image based on a scan signal and an emission control signal transferred from the gate driving circuit 120 through the plurality of gate lines GL and the data voltage transferred from the data driving circuit 130 through the plurality of data lines DL.

In the case of a liquid crystal display, the display panel 110 may include a liquid crystal layer formed between two substrates and may be operated in any known mode, such as a twisted nematic (TN) mode, a vertical alignment (VA) mode, an in-plane switching (IPS) mode, or a fringe field switching (FFS) mode. In the case of an organic light emitting display, the display panel 110 may be implemented in a top emission scheme, a bottom emission scheme, or a dual-emission scheme.

In the display panel 110, a plurality of pixels may be arranged in a matrix form, and each pixel may include subpixels SP having different colors, e.g., a white subpixel, a red subpixel, a green subpixel, and a blue subpixel, and each subpixel SP may be defined by the plurality of data lines DL and the plurality of gate lines GL.

One subpixel SP may include, e.g., a thin film transistor (TFT) formed at the intersection between one data line DL and one gate line GL, a light emitting element, such as an organic light emitting diode, charged with the data voltage, and a storage capacitor electrically connected to the light emitting element to maintain the voltage.

For example, when the display device 100 having a resolution of 2,160×3,840 includes four subpixels SP of white (W), red (R), green (G), and blue (B), 3,840 data lines DL may be connected to 2,160 gate lines GL and four subpixels WRGB, and thus, there may be provided 3,840×4=15,360 data lines DL. Each subpixel SP is disposed at the intersection between the gate line GL and the data line DL.

The gate driving circuit 120 may be controlled by the controller 140 to sequentially output scan signals to the plurality of gate lines GL disposed in the display panel 110, controlling the driving timing of the plurality of subpixels SP.

In the display device 100 having a resolution of 2,160×3,840, sequentially outputting the scan signal to the 2,160 gate lines GL from the first gate line to the 2,160th gate line may be referred to as 2,160-phase driving. Sequentially outputting the scan signal to each unit of four gate lines GL, e.g., sequentially outputting the scan signal to the fifth gate line to the eighth gate line after sequentially outputting the scan signal to the first gate line to the fourth gate line, is referred to as 4-phase driving. In other words, sequentially outputting the scan signal to every N gate lines GL may be referred to as N-phase driving.

The gate driving circuit 120 may include one or more gate driving integrated circuits (GDICs). Depending on driving schemes, the gate driving circuit 120 may be positioned on only one side, or each of two opposite sides, of the display panel 110. The gate driving circuit 120 may be implemented in a gate-in-panel (GIP) form which is embedded in the bezel area of the display panel 110.

The data driving circuit 130 receives image data DATA from the controller 140 and convert the received image data DATA into an analog data voltage. Then, as the data voltage is output to each data line DL according to the timing when the scan signal is applied through the gate line GL, each subpixel SP connected to the data line DL displays a light emission signal having the brightness corresponding to the data voltage.

Likewise, the data driving circuit 130 may include one or more source driving integrated circuits SDIC, and the source driving integrated circuit SDIC may be connected to the bonding pad of the display panel 110 in a tape automated bonding (TAB) type or a chip-on-glass (COG) type or may be disposed directly on the display panel 110.

In some cases, each source driving integrated circuit SDIC may be integrated and disposed on the display panel 110. Further, each source driving integrated circuit SDIC may be implemented in a chip-on-film (COF) type and, in this case, each source driving integrated circuit SDIC may be mounted on a circuit film and may be electrically connected to the data line DL of the display panel 110 through the circuit film.

The controller 140 supplies various control signals to the gate driving circuit 120 and the data driving circuit 130 and controls the operation of the gate driving circuit 120 and the data driving circuit 130. In other words, the controller 140 may control the gate driving circuit 120 to output a scan signal according to the timing implemented in each frame and, on the other hand, transfers the image data DATA received from the outside to the data driving circuit 130.

In this case, the controller 140 receives, from an external host system 160, several timing signals including, e.g., a vertical synchronization signal Vsync, a horizontal synchronization signal Hsync, a data enable signal DE, and a main clock MCLK, together with the image data DATA.

The host system 160 may be any one of a television (TV) system, a set-top box, a navigation system, a personal computer (PC), a home theater system, a mobile device, and a wearable device.

Accordingly, the controller 140 may generate a control signal according to various timing signals received from the host system 160 and transfers the control signal to the gate driving circuit 120 and the data driving circuit 130.

For example, the controller 140 outputs several gate control signals including, e.g., a gate start pulse GSP, a gate clock GCLK, and a gate output enable signal GOE, to control the gate driving circuit 120. The gate start pulse GSP controls the timing at which one or more gate driving integrated circuits GDIC constituting the gate driving circuit 120 start operation. The gate clock GCLK is a clock signal commonly input to one or more gate driving integrated circuits GDIC and controls the shift timing of the scan signal. The gate output enable signal GOE designates timing information about one or more gate driving integrated circuits GDICs.

The controller 140 outputs various data control signals including, e.g., a source start pulse SSP, a source sampling clock SCLK, and a source output enable signal SOE, to control the data driving circuit 130. The source start pulse SSP controls the timing at which one or more source driving integrated circuits SDIC constituting the data driving circuit 130 start data sampling. The source sampling clock SCLK is a clock signal that controls the timing of sampling data in the source driving integrated circuit SDIC. The source output enable signal SOE controls the output timing of the data driving circuit 130.

The display device 100 may further include a power management circuit 150 that supplies various voltages or currents to, e.g., the display panel 110, the gate driving circuit 120, and the data driving circuit 130 or controls various voltages or currents to be supplied.

The power management circuit 150 adjusts the direct current (DC) input voltage Vin supplied from the host system 160, generating power required to drive the display panel 110, the gate driving circuit 120, and the data driving circuit 130.

The subpixel SP is positioned at the intersection between the gate line GL and the data line DL, and a light emitting element may be disposed in each subpixel SP. For example, the organic light emitting diode display may include a light emitting element, such as an organic light emitting diode, in each subpixel SP and may display an image by controlling the current flowing to the light emitting element according to the data voltage.

The display device 100 may be one of various types of devices, such as liquid crystal displays, organic light emitting diode displays, or plasma display panels.

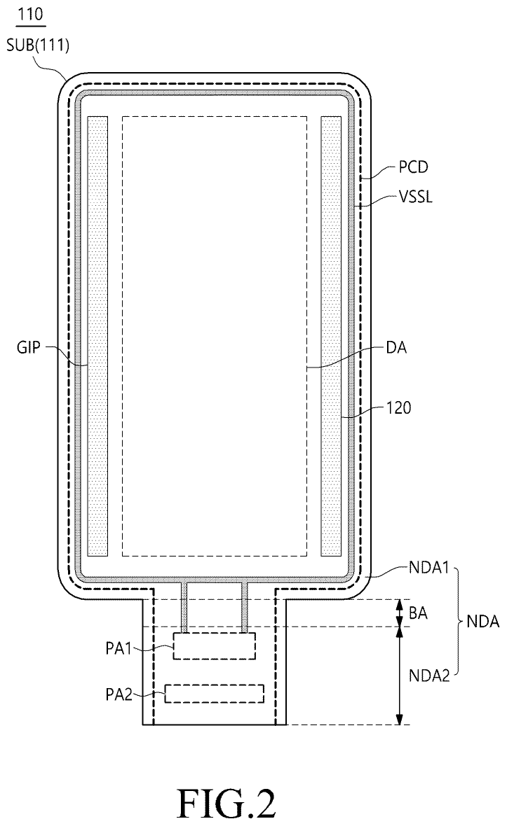

FIG. 2 is a view illustrating a bending structure and a wiring structure in a planar structure of a display panel 110 according to embodiments of the disclosure.

Referring to FIG. 2, the substrate 111 of the display panel 110 according to embodiments of the disclosure may include a display area DA and a non-display area NDA. The display area DA and the non-display area NDA may be areas of the display panel 110.

All of the lines and electrodes are formed on the substrate 111. In the display device 100 according to embodiments of the disclosure, the substrate 111 may be a flexible substrate capable of bending. In the disclosure, “bending” may have a meaning equivalent to “folding” or “flexible.”

The non-display area NDA is an area where an image is not displayed, and may be an area except for the display area DA. The subpixel SP is not disposed in the non-display area NDA. However, at least one dummy subpixel that is not directly involved in image display may be disposed in the non-display area NDA.

The non-display area NDA may include a first non-display area NDA1, a bending area BA, and a second non-display area NDA2.

The first non-display area NDA1 may be positioned around the display area DA, and may be an area closest to the display area DA among the first non-display area NDA1, the bending area BA, and the second non-display area NDA2.

The second non-display area NDA2 may include pad areas PA1 and PA2 where various pads are disposed, and may be an area farthest from the display area DA among the first non-display area NDA1, the bending area BA, and the second non-display area NDA2.

The bending area BA is an area where the substrate 111 is bent, and may be an area positioned between the first non-display area NDA1 and the second non-display area NDA2.

The substrate 111 may include a display area DA in which images are displayed and a non-display area NDA which is an area outside of the display area DA. A plurality of subpixels SP may be disposed in the display area DA. The non-display area NDA may include a gate in panel (GIP) area where a GIP-type gate driving circuit is formed, a bending area BA where various lines pass and a data driving circuit is electrically connected, and a second non-display area NDA2.

For example, the gate in panel (GIP) area may be positioned in the left outer area and/or the right outer area of the display area DA. The non-display area NDA may be positioned in an upper outer area (or a lower outer area) of the display area DA. The second non-display area NDA2 may be an outer area than the bending area BA, and may include pad areas PA1 and PA2 to which circuit components such as a printed circuit board are electrically connected.

As described above, the substrates (SUB) 111 may include a bending area BA that is bent and folded, and the bending area BA may be folded to be positioned on the lower surface of the unfolded portion. The bending area BA is a partial area of the non-display area NDA, and may be positioned in the driving circuit area to which the data driving circuit is electrically connected and between the driving circuit area and the display area DA.

According to the structure of the subpixel SP, for driving the subpixel SP, a plurality of driving voltage lines DVL for supplying the driving voltage VDD to the subpixel SP and one or more base voltage lines VSSL for applying the base voltage VSS to the common electrode CE of the light emitting element ED in each subpixel SP may be further disposed on the substrates (SUB) 111.

For example, the plurality of driving voltage lines DVL may be disposed in the column direction, but the disclosure is not limited thereto. In order to efficiently transfer the driving voltage VDD to the plurality of driving voltage lines DVL, a driving voltage pattern integrally or electrically connected to the plurality of driving voltage lines DVL may be disposed in the non-display area NDA.

The plurality of driving voltage lines DVL may electrically connect the bending area BA to the data driving circuit or the printed circuit board connected to the pad areas PA1 and PA2 through the driving voltage pattern.

One or more base voltage lines VSSL may be disposed in the non-display area NDA to surround an outer area of the display area DA for efficient transfer of the base voltage VSS. Further, one or more base voltage lines VSSL may be electrically connected to the data driving circuit or the printed circuit board connected to the driving circuit area past the bending area BA.

A crack prevention pattern PCD may be formed on the substrates (SUB) 111. The crack prevention pattern PCD may be formed outside the base voltage line VSSL in the non-display area NDA, but the disclosure is not limited thereto.

For example, the crack prevention pattern PCD is a pattern for preventing cracks in lines passing through the substrate SUB 111, and may be formed in a zigzag pattern, but the disclosure is not limited thereto.

For example, when the bending area BA is bent, some of the signal lines passing through the bending area BA may be cracked (electrically opened) or short-circuited with neighboring signal lines. In this case, an accurate signal may not be transferred through a signal line that is cracked (opened) or short-circuited, and thus a problem with display driving or an image display may not be properly performed, and thus image quality may be greatly decreased. Thus, to prevent such issues, the crack prevention pattern PCD may be disposed, but the disclosure is not limited thereto.

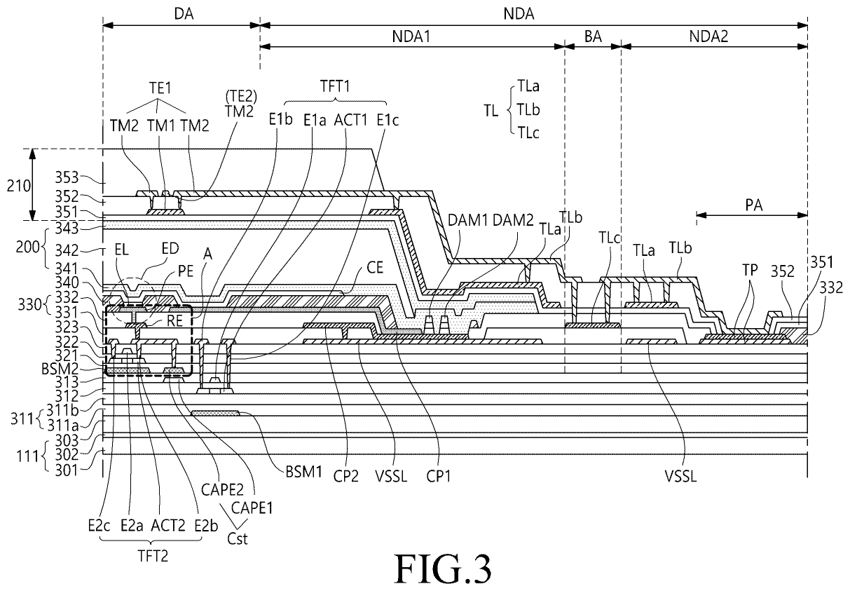

In the above-described display panel 110, as the flexible substrate (SUB) 111 is used, and the bending area BA which is a portion to which the data driving circuit is connected is bent, a portion of the substrate (SUB) 111 is folded backward. The folded bending area BA which is a portion which an image cannot be displayed is not visible from the front. Accordingly, use of a bending structure and a line arrangement structure as illustrated in FIG. 3 may significantly reduce the bezel size, and the narrow bezel design may provide a high aesthetic design.

FIG. 3 is a view illustrating an example of a cross-sectional structure of the display panel 110 of FIG. 2 according to embodiments of the disclosure.

Referring to FIG. 3, the display panel 110 according to embodiments of the disclosure may include a substrate 111, a transistor unit, a light emitting element unit, and an encapsulation unit, but embodiments of the disclosure are not limited thereto.

The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer, but embodiments of the disclosure are not limited thereto. The intermediate substrate layer 302 may be an inorganic insulation layer, but embodiments of the disclosure are not limited thereto. When an electric charge is charged to the first substrate 301 which is a polyimide layer, the intermediate substrate layer 302 may prevent the electric charge from affecting transistors disposed on the second substrate 303 through the second substrate 303 which is a polyimide layer.

Further, the intermediate substrate layer 302 may prevent a moisture component from penetrating upward through the first substrate 301. For example, the intermediate substrate layer 302 may be formed of a single layer of silicon nitride (SiNx) or silicon oxide (SiOx) or multiple layers thereof, or may be formed of a double layer of silicon dioxide (SiO2) and silicon nitride (SiNx), but is not limited thereto.

The transistor unit may include an insulation layer 311, 312, 313, 321, 322, and 323 on the substrate 111, thin film transistors TFT1 and TFT2, a storage capacitor CST, and various electrodes or signal lines.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, However, embodiments of the disclosure are not limited thereto.

The first active layer ACT1 may include a first semiconductor material. For example, the first semiconductor material may include an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 may include a second semiconductor material. For example, the second semiconductor material may include an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

The type of the semiconductor material of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The purposes of the transistors in the display area DA may be as follows.

For example, all of the transistors in each subpixel SP may be implemented as first thin film transistors TFT1. As another example, all of the transistors in each subpixel SP may be implemented as second thin film transistors TFT2. As another example, some of all of the transistors in each subpixel SP may be implemented as first thin film transistors TFT1, and the others of the transistors may be implemented as second thin film transistors TFT2. In other words, each subpixel SP may include at least one first thin film transistor TFT1 and at least one second thin film transistor TFT2.

When some of all of the transistors in each subpixel SP are implemented as first thin film transistors TFT1 and the others are implemented as second thin film transistors TFT2, the following examples may be possible.

For example, in each subpixel SP, the driving transistor DT may be implemented as a first thin film transistor TFT1, and other transistors (e.g., the scan transistor ST, the emission control transistor, etc.) than the driving transistor DT may be implemented as second thin film transistors TFT2.

As another example, in each subpixel SP, the driving transistor DT may be implemented as a second thin film transistor TFT2, and other transistors (e.g., the scan transistor ST, the emission control transistor, etc.) than the driving transistor DT may be implemented as first thin film transistors TFT1.

The second thin film transistor TFT2 connected to the pixel electrode PE of the light emitting element ED may be a driving transistor DT or a transistor different from the driving transistor DT according to the configuration of the subpixel circuit SPC. For example, the second thin film transistor TFT2 connected to the pixel electrode PE of the light emitting element ED may be an emission control transistor connected between the driving transistor DT and the light emitting element ED.

The purposes of the transistors in the non-display area NDA may be as follows.

For example, the active layers of the transistors included in the gate-in-panel (GIP) type gate driving circuit may be formed of an oxide semiconductor material. As another example, the active layers of the transistors included in the gate-in-panel (GIP) type gate driving circuit may be formed of a low-temperature polysilicon semiconductor material. As another example, among the transistors included in the gate-in-panel (GIP) type gate driving circuit, some active layers may be formed of a low-temperature polysilicon semiconductor material, and other active layers may be formed of an oxide semiconductor material.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The storage capacitor CST may be disposed in various metal layers in the display panel 110. For example, the storage capacitor CST may include a first capacitor electrode CAPE1 and a second capacitor electrode CAPE2.

The light emitting element portion may include a plurality of light emitting elements ED disposed on the planarization layer 330. Each of the plurality of light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers, but embodiments of the disclosure are not limited thereto. In addition to the encapsulation layer 200, the encapsulation unit may further include at least one dam DAM for preventing a material constituting the encapsulation layer 200 from overflowing. In particular, when the second encapsulation layer 342 included in the encapsulation layer 200 is an organic encapsulation layer formed of an organic material, the dam DAM may prevent the organic material from overflowing.

Hereinafter, a structure or a vertical structure of the display panel 110 according to embodiments of the disclosure is described in more detail.

The first buffer layer 311 may be disposed on the substrate 111. The first buffer layer 311 may be a single layer or multiple layers, but embodiments of the disclosure are not limited thereto. When the first buffer layer 311 includes multiple layers, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first inter-layer insulation layer 313 may be disposed on the first gate electrode E1a of the first thin film transistor TFT1. Here, the metal layer where the first gate electrode E1a of the first thin film transistor TFT1 is disposed may be referred to as a gate metal layer.

The second buffer layer 321 may be disposed on the first inter-layer insulation layer 313.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed. The second inter-layer insulation layer 323 may be disposed on the second gate electrode E2a of the second thin film transistor TFT2. Here, the second gate electrode E2a of the second thin film transistor TFT2 may be referred to as a second gate metal layer.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in the first source-drain metal layer.

For example, the storage capacitor CST may be formed by a first capacitor electrode CAPE1 and a second capacitor electrode CAPE2. In some cases, the storage capacitor CST may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first gate insulation layer 312 and may be disposed in the first gate metal layer, but embodiments of the disclosure are not limited thereto. For example, the second capacitor electrode CAPE2 may be disposed on the first inter-layer insulation layer 313.

The second source electrode E2b of the second thin film transistor TFT2 may be electrically connected to the second capacitor electrode CAPE2 through holes of the second inter-layer insulation layer 323, the second gate insulation layer 322, and the second buffer layer 321.

The transistor unit may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor unit may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first inter-layer insulation layer 313 and the second buffer layer 321. The second shield pattern BSM2 may be disposed in the same metal layer as the second capacitor electrode CAPE2, but embodiments of the disclosure are not limited thereto. As another example, the second shield pattern BSM2 may be disposed in the same first gate metal layer as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulation layer including an organic insulating material.

For example, the planarization layer 330 may be constituted of one layer. As another example, the planarization layer 330 may include two layers. The planarization layer 330 may include a first planarization layer 331 and a second planarization layer 332. As another example, the planarization layer 330 may include three or more layers. Embodiments of the disclosure are not limited thereto.

The first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

A connection electrode RE may be disposed on the first planarization layer 331. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through the hole of the first planarization layer 331. The second source electrode E2b of the second thin film transistor TFT2 may be electrically connected to the second capacitor electrode CAPE2 of the storage capacitor CST.

The connection electrode RE may be disposed in the second source-drain metal layer on the first planarization layer 331 and may include a second source-drain metal.

The second planarization layer 332 may be disposed on the connection electrode RE.

The light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The opening of the bank 340 may expose a portion of the pixel electrode PE to form the emission area. The opening of the bank 340 may overlap a portion of the pixel electrode PE.

For example, the bank 340 may be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

The intermediate layer EL of the light emitting element ED may be disposed on a portion of the pixel electrode PE and the bank 340. The common electrode CE may be disposed on the intermediate layer EL.

The encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the disclosure are not limited thereto.

For example, the encapsulation layer 200 may include a first encapsulation layer 341, a second encapsulation layer 342, and a third encapsulation layer 343, but embodiments of the disclosure are not limited thereto. For example, the first encapsulation layer 341 and the third encapsulation layer 343 may include an inorganic layer, and the second encapsulation layer 342 may include an organic layer, but embodiments of the disclosure are not limited thereto.

The display panel 110 according to embodiments of the disclosure may have a built-in touch sensor. In this case, the display panel 110 according to embodiments of the disclosure may include a touch sensor layer 210 disposed on the encapsulation layer 200 and having a touch sensor.

The touch sensor layer 210 may include a plurality of touch electrodes TE corresponding to touch sensors, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, to form the plurality of touch electrodes TE. In this case, the touch sensor layer 210 may further include a touch interlayer insulation layer 352 disposed between the first touch metal layer and the second touch metal layer.

For example, one of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute one first touch electrode TE1. In this case, two or more second touch electrodes TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulation layer 352 may be disposed on the first touch metal layer.

The touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material, the touch interlayer insulation layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulation layer 352 may extend from the display area DA to the non-display area NDA. The touch protection layer 353 may be disposed to extend from the display area DA to the non-display area NDA.

The touch routing line TL may electrically connect the touch electrode TE and the touch pad TP. The touch routing line TL may be formed of at least one of the first touch metal TM1 and the second touch metal TM2.

For example, the touch routing line TL may be formed of the first touch metal TM1, or the touch routing line TL may be formed of the second touch metal TM2, or the first touch metal TM1 and the second touch metal TM2. When one touch routing line TL is formed of the first touch metal TM1 and the second touch metal TM2, the first touch metal TM1 and the second touch metal TM2 constituting one touch routing line TL may be electrically connected through a hole in the touch interlayer insulation layer 352.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section where two signal paths are connected in parallel.

The touch routing line TL may be disposed along the inclined surface of the encapsulation layer 200, and may extend to the touch pad TP through the upper portion of the dam DAM1 and DAM2.

The touch buffer layer 351 may have an opening exposing at least a portion of the touch pad TP. The touch routing line TL may be electrically connected to the touch pad TP through the opening of the touch buffer layer 351. The touch interlayer insulation layer 352 may be disposed on the touch routing line TL, and may extend to an area where the touch pad TP is disposed. The touch protection layer 353 may be disposed only in the display area DA, or may extend to the non-display area NDA to be disposed on the touch routing line TL. In some cases, the touch protection layer 353 may further extend to the upper portion of the touch pad TP.

Each of the plurality of touch electrodes TE may be a mesh-type electrode having a plurality of openings. In this case, each of the plurality of touch electrodes TE may be formed of at least one second touch metal TM2. However, embodiments of the disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1, which are bridge metals. For example, the two second touch metals TM2 spaced apart from each other may be electrically connected by the first touch metal TM1 to constitute one first touch electrode TE1.

The plurality of first touch metals TM1 and the plurality of second touch metals TM2 may be disposed not to overlap the light emitting element ED. The plurality of first touch metals TM1 and the plurality of second touch metals TM2 may overlap the bank 340. Accordingly, the luminous efficiency of the light emitting element ED may increase.

The touch routing line TL may connect the touch pad TP disposed in the pad area PA in the second non-display area NDA2 and the first touch electrode TE1 disposed in the display area DA. To that end, the touch routing line TL may be disposed across the second non-display area NDA2, the bending area BA, and the first non-display area NDA1.

The touch routing line TL may include a first line section TLa, a second line section TLb, and a third line section TLc. For example, the touch routing line TL may include the first line section TLa and the second line section TLb disposed in the first non-display area NDA1 and the second non-display area NDA2, and the third line section TLc disposed in the bending area BA. The third line section TLc may connect the first line section TLa and the second line section TLb.

The first line section TLa of the touch routing line TL is a single line section, and may further include a third touch metal layer where the third touch metal TM3 is disposed.

The first line section TLa of the touch routing line TL may extend along the inclined surface of the encapsulation layer 200 and may extend via the upper portion of at least one dam DAM1 or DAM2.

For example, the first line section TLa of the touch routing line TL may lead to the third line section TLc of the touch routing line TL through at least one of the first touch metal layer and the second touch metal layer.

The second line section TLb of the touch routing line TL may include at least one of a first touch metal layer where the first touch metal TM1 is disposed and a second touch metal layer where the second touch metal TM2 is disposed.

For example, the second line section TLb of the touch routing line TL may be formed of a second touch metal layer. As another example, the second line section TLb of the touch routing line TL may be configured by electrically connecting the first touch metal layer and the second touch metal layer.

For example, the second line section TLb of the touch routing line TL may be electrically connected to the touch pad TP through a contact hole (opening) that penetrates the second planarization layer 332, the touch buffer layer 351, and the touch interlayer insulation layer 352.

For example, the third line section TLc of the touch routing line TL may lead to the second line section TLb of the touch routing line TL.

The third line section TLc of the touch routing line TL may include a metal layer different from the first to third touch metal layers where the first to third touch metals TM1, TM2, and TM3 are disposed. For example, the metal layer included in the third line section TLc of the touch routing line TL may be the same as the metal layer where the electrode or line for display driving is disposed. For example, the metal layer included in the third line section TLc of the touch routing line TL may include a metal layer where the pixel electrode PE is disposed, but the disclosure is not limited thereto.

The touch pad TP is electrically connected to the second line section TLb of the touch routing line TL, and may include a metal layer different from the first to third touch metal layers. For example, the metal layer included in the touch pad TP may be the same as the metal layer where the electrode or line for display driving is disposed. For example, the metal layer included in the touch pad TP may include a metal layer where the pixel electrode PE is disposed, but the disclosure is not limited thereto.

The display panel 110 according to embodiments of the disclosure may further include a common voltage line VSSL to which the common voltage VSS is applied and a connection pattern connecting the common electrode CE and the common voltage line VSSL.

For example, the connection pattern may include a first connection pattern CP1 and a second connection pattern CP2.

For example, the first connection pattern CP1 may connect the common electrode CE and the second connection pattern CP2, and the second connection pattern CP2 may connect the first connection pattern CP1 and the common voltage line VSSL, but embodiments of the disclosure are not limited thereto.

For example, the first connection pattern CP1 may include the same material as that of the pixel electrode PE. The second connection pattern CP2 may include the same material as the connection electrode RE.

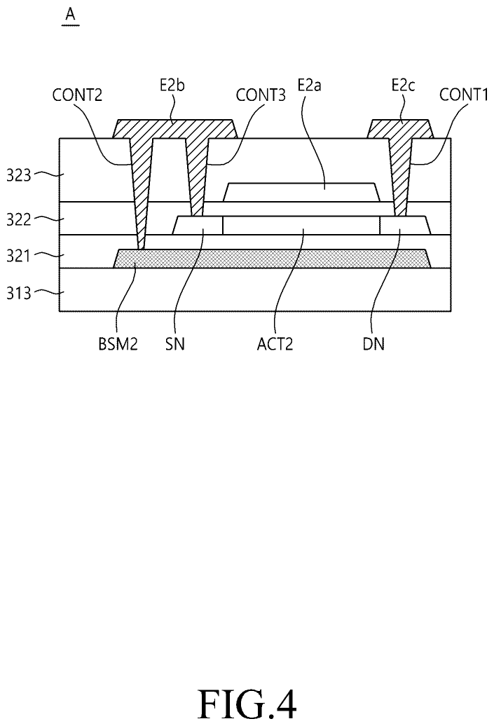

FIG. 4 is a cross-sectional view illustrating a driving transistor, taken along area A of FIG. 3, according to embodiments of the disclosure.

Any description of area A that overlaps with the description in FIG. 3 may be skipped.

Referring to FIG. 4, a second shield pattern BSM2 may be disposed on the first inter-layer insulation layer 313. The second shield pattern BSM2 may be formed to protect the second active layer ACT2 of the driving transistor from external environmental influences or interference.

The second shield pattern BSM2 may be formed to extend, unlike in FIG. 3. As the second shield pattern BSM2 is formed to extend, it may contact the source electrode E2b through the second contact hole CONT2 formed in the second gate insulation layer 322 and the second interlayer insulation layer 323.

A second buffer layer 321 may be disposed on the first inter-layer insulation layer 313.

A drain node DN, the source node SN, and a second active layer ACT2 may be disposed on the second buffer layer 321. The drain node DN may contact the second drain electrode E2c through the first contact hole CONT1.

The drain node DN and the source node SN may overlap the second shield pattern BSM2. Accordingly, a capacitance may be formed between the drain node DN and the second shield pattern BSM2. As the voltage input to the drain node DN increases due to capacitive coupling as capacitance is formed, the voltage of the second shield pattern BSM2 may also increase.

If the voltage of the second shield pattern BSM2 increases, the voltage of the source node SN may also increase. The source node SN may contact the source electrode E2b through the third contact hole CONT3. Accordingly, when the voltage of the source node SN increases, the voltage of the source electrode E2b may increase, and the voltage of the pixel electrode PE, which is electrically connected to the source electrode E2b through the connection electrode RE, may also increase.

In other words, when the voltage of the drain node DN increases, the voltage of the pixel electrode PE may increase due to the capacitive coupling. As the voltage of the pixel electrode PE increases, the light emitting element ED may be changed from a turn-off state to a turn-on state. A black screen may be displayed in the display area DA when the light emitting element ED is turned on in an unintended period.

In some embodiments, the shield pattern (e.g., BSM2) may overlap both the source node SN and the drain node DN to form capacitive coupling structures that stabilize node voltages prior to light emission. In particular, the overlap area between the shield pattern and the source node SN may be greater than the overlap area between the shield pattern and the drain node DN. By increasing the capacitive coupling strength at the source node SN, the voltage of the source node SN can be more effectively stabilized during pre-emission operations, thereby improving the uniformity and reliability of the voltage supplied to the pixel electrode. This configuration further enhances charge retention at the source node SN while minimizing potential voltage loss or instability that could affect the light emitting element's operation. Alternatively, the overlap areas may be selectively adjusted based on desired capacitive characteristics for the drain node DN and source node SN, respectively.

As noted, the shield pattern overlaps the source node and drain node to provide capacitive coupling for voltage stabilization. For effective capacitive coupling, it is beneficial for one electrode, such as the shield pattern, to be connected to a stable potential, such as ground, common voltage, or another fixed voltage reference. Accordingly, in some embodiments, the shield pattern may be electrically connected to a fixed voltage line, a ground line, or a common voltage line. Connecting the shield pattern to a stable potential enhances the capacitive coupling effect between the drain node, the source node, and the shield pattern, thereby improving voltage stabilization prior to light emission.

A subpixel SP for preventing a black screen from being displayed in the display area DA is described below.

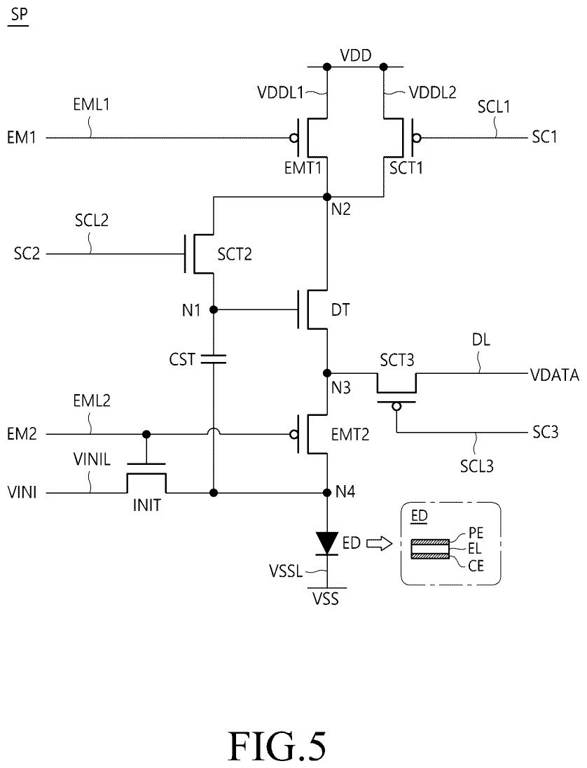

FIG. 5 is a view illustrating an equivalent circuit of a subpixel SP according to embodiments of the disclosure.

Referring to FIG. 5, the subpixel SP may include a driving transistor DT, a light emitting element ED, a first emission control transistor EMT1, a second emission control transistor EMT2, a first scan transistor SCT1, a second scan transistor SCT2, a third scan transistor SCT3, and a storage capacitor CST.

Hereinafter, in the example described below, the driving transistor DT, the second scan transistor SCT2, and the initialization transistor INIT are oxide semiconductor transistors, and the first emission control transistor EMT1, the second emission control transistor EMT2, the first scan transistor SCT1, and the third scan transistor SCT3 are low-temperature polycrystalline silicon (LTPS) semiconductors, but the configuration of active layers of the plurality of transistors may be changed.

Although, in the example described below, the first emission control transistor EMT1, the second emission control transistor EMT2, the first scan transistor SCT1, and the third scan transistor SCT3 are P-type transistors, the first emission control transistor EMT1, the second emission control transistor EMT2, the first scan transistor SCT1, and the third scan transistor SCT3 may be N-type transistors.

As the first emission control transistor EMT1, the second emission control transistor EMT2, the first scan transistor SCT1, and the third scan transistor SCT3 are formed as P-type transistors, there may be advantages in the process for forming the subpixel SP. For example, the number of mask processes for forming the subpixel SP may be decreased. As the number of mask processes decreases, the required number of masks may decrease. If the number of masks is decreased, the cost required for the process may be decreased.

The light emitting element ED may include a pixel electrode PE, an intermediate layer EL, and a common electrode CE.

The pixel electrode PE of the light emitting element ED may be an anode electrode or a cathode electrode. The common electrode CE may be a cathode electrode or an anode electrode.

The driving transistor DT may be a transistor for supplying a driving current to the light emitting element ED for light emission of the light emitting element ED. The driving transistor DT may include a first node N1, a second node N2, and a third node N3.

The first node N1 may be a node corresponding to a gate node. The first node N1 may be connected to the second scan transistor SCT2. Electrical connection of the second node N2 and the third node N3 may be controlled according to the voltage input to the first node N1.

Hereinafter, for convenience of description, an example is described where the second node N2 is a drain node and the third node N3 is a source node, but the second node N2 may be a source node and the third node N3 may be a drain node.

The second node N2 may be a source node. The second node N2 may be connected to the first emission control transistor EMT1 and the first scan transistor SCT1.

The first emission control transistor EMT1 may be electrically connected to the first driving voltage line VDDL1 to which the driving voltage VDD is input. The gate node of the first emission control transistor EMT1 may be electrically connected to the first emission control signal line EML1 to which the first emission control signal EM1 is input. The first emission control transistor EMT1 may be turned on or turned off according to the first emission control signal EM1 to control the electrical connection between the first driving voltage line VDDL1 and the second node N2.

The first scan transistor SCT1 may be connected to the second driving voltage line VDDL2 to which the driving voltage VDD is input. Accordingly, as the first emission control transistor EMT1 or the first scan transistor SCT1 is turned on, the second node N2 may receive the driving voltage VDD. In other words, the first emission control transistor EMT1 or the first scan transistor SCT1 is selectively turned on to perform the precharging. In addition, for example, the gate node of the first scan transistor SCT1 may be electrically connected to the first scan signal line SCL1 into which the first scan signal SC1 is input, and the gate node of the second scan transistor SCT2 may be electrically connected to the second scan signal line SCL2 into which the second scan signal SC2 is input.

The third node N3 may be a drain node. The third node N3 may be connected to the third scan transistor SCT3 and the second emission control transistor EMT2.

The gate node of the second emission control transistor EMT2 may be electrically connected to the second emission control signal line EML2 to which the second emission control signal EM2 is input. The second emission control transistor EMT2 may be turned on or turned off according to the second emission control signal EM2 to control the electrical connection between the third node N3 and the fourth node N4.

The gate node of the third scan transistor SCT3 may be electrically connected to the third scan signal line SCL3 into which the third scan signal SC3 is input. The third scan transistor SCT3 may control the electrical connection between the data line DL to which the data voltage VDATA is input and the third node N3 according to the third scan signal SC3.

The gate node of the initialization transistor INIT may be connected to the second emission control signal line EML2 to which the second emission control signal EM2 is input. The initialization transistor INIT may control the electrical connection between the fourth node N4 and the initialization voltage line VINIL to which the initialization voltage VINI is input according to the second emission control signal EM2.

The storage capacitor CST may be electrically connected between the gate node (i.e., the first node N1) of the driving transistor DT and the fourth node N4 connected to the pixel electrode PE of the light emitting element ED, and may maintain the voltage for one frame.

The light emitting element ED may be electrically connected to the base voltage line VSSL to which the base voltage VSS of the light emitting element ED is input. The light emitting element ED may be turned on by a potential difference between the fourth node N4 and the base voltage VSS.

Hereinafter, the gate driving circuit 120 for supplying the gate signals EM1, EM2, SC1, SC2, and SC3 of the subpixel SP may be described.

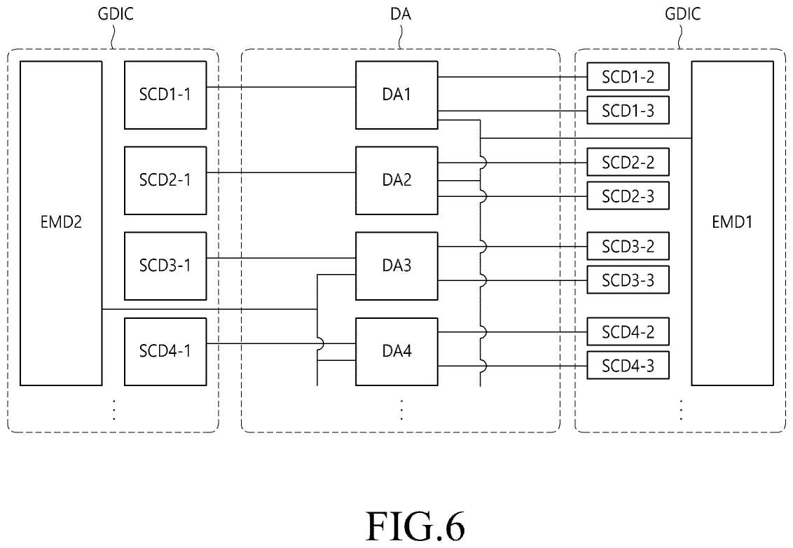

FIG. 6 is a view illustrating a connection relationship between a gate driving integrated circuit GDIC and a display area DA according to various embodiments of the disclosure.

Referring to FIG. 6, the display device 100 may include a display area DA where a plurality of subpixels SP are disposed, and a gate driving integrated circuit GDIC disposed on two opposite sides of the display area DA.

The display area DA may include a first display area DA1, a second display area DA2, a third display area DA3, and a fourth display area DA4. Further, the display area DA may include more Nth display area according to the resolution. For example, the display area DA may include the first display area DA1 to the 2160th display area, when the display device 100 having a resolution of 2,160×3,840 sequentially outputs scan signals to the first gate line to the 2,160th gate line GL.

The plurality of subpixels SP may be disposed in the form of a matrix in the display area DA. The first display area DA1 may be an area where a plurality of subpixels SP disposed in the first row of the display area DA are positioned. The second display area DA2 may be an area where a plurality of subpixels SP disposed in the second row of the display area DA are positioned. The third display area DA3 may be an area where a plurality of subpixels SP disposed in the third row of the display area DA are positioned. The fourth display area DA4 may be an area where a plurality of subpixels SP disposed in the fourth row of the display area DA are positioned.

The gate driving integrated circuit GDIC may include a first emission control driver EMD1, a second emission control driver EMD2, a 1-1th scan driver SCD1-1, a 1-2th scan driver SCD1-2, a 2-1th scan driver SCD2-1, a 2-2th scan driver SCD2-2, a 2-3th scan driver SCD2-3, a 3-1th scan driver SCD3-1, a 3-2th scan driver SCD3-2, a 3-3th scan driver SCD3-3, a 4-1th scan driver SCD4-1, a 4-2th scan driver SCD4-2, and a 4-3th scan driver SCD4-3.

More emission control drivers and scan drivers may be included according to the resolution of the display device 100. The emission control driver (e.g., the first emission control driver EMD1) may output the emission control signal EM. The scan driver (e.g., the 1-1th scan driver SCD1-1) may output the scan signal SC.

For example, the plurality of subpixels SP disposed in the first display area DA1 may receive the first scan signal SC1 from the 1-1th scan driver SCD1-1, the second scan signal SC2 from the 1-2th scan driver SCD1-2, and the third scan signal SC3 from the 1-3th scan driver SCD1-3.

For example, the plurality of subpixels SP disposed in the second display area DA2 may receive the first scan signal SC1 from the 2-1th scan driver SCD2-1, the second scan signal SC2 from the 2-2th scan driver SCD2-2, and the third scan signal SC3 from the 2-3th scan driver SCD2-3.

For example, the plurality of subpixels SP disposed in the third display area DA3 may receive the first scan signal SC1 from the 3-1th scan driver SCD3-1, the second scan signal SC2 from the 3-2th scan driver SCD3-2, and the third scan signal SC3 from the 3-3th scan driver SCD3-3.

For example, the plurality of subpixels SP disposed in the fourth display area DA4 may receive the first scan signal SC1 from the 4-1th scan driver SCD4-1, the second scan signal SC2 from the 4-2th scan driver SCD4-2, and the third scan signal SC3 from the 4-3th scan driver SCD4-3.

For example, the first emission control driver EMD1 may output the first emission control signal EM1 to the plurality of subpixels SP disposed in the first display area DA1 and the second display area DA2, and output the second emission control signal EM2 to the plurality of subpixels SP disposed in the fifth display area and the sixth display area.

For example, the second emission control driver EMD2 may output the first emission control signal EM1 to the plurality of subpixels SP disposed in the third display area DA3 and the fourth display area DA4, and output the second emission control signal EM2 to the plurality of subpixels SP disposed in the seventh display area and the eighth display area.

An example of the gate driving integrated circuit GDIC illustrated in FIG. 6 may be variously implemented according to the type of the display device 100.

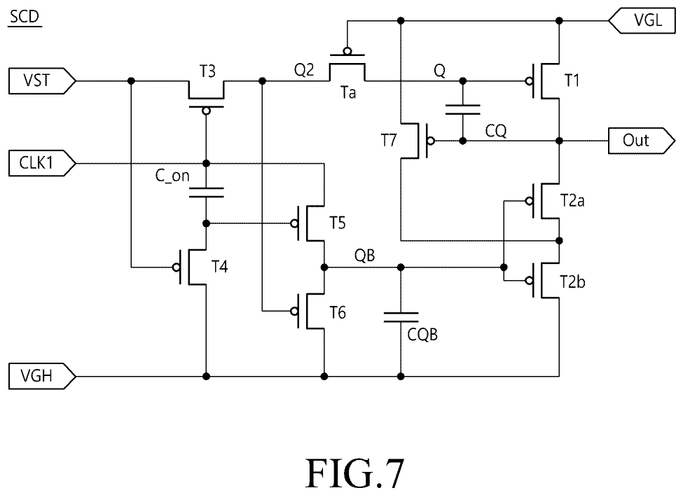

FIG. 7 is a view illustrating a scan driver SCD according to various embodiments of the disclosure.

The equivalent circuit diagram of the scan driver SCD illustrated in FIG. 7 may be illustrated as an equivalent circuit diagram of a plurality of scan drivers SCD1-1, SCD2-1, SCD3-1, and SCD4-1 outputting the first scan signal SC1.

Referring to FIG. 7, the scan driver SCD may include a plurality of transistors T1, T2a, T2b, T3, T4, T5, T6, and Ta and at least one capacitor CQ, CQB, and C_on.

The first transistor T1 may control the electrical connection between the input terminal of the second gate driving voltage VGL and the output terminal OUT of the scan signal according to the voltage of the Q node Q.

The Q node capacitor CQ may be connected between the output terminal OUT of the scan signal and the Q node Q, and may form a capacitance between the output terminal OUT of the scan signal and the Q node Q. The capacitance of the Q node capacitor CQ may be larger than the capacitance of the C_on capacitor C_on and the capacitance of the CQB capacitor CQB.

The 2ath transistor T2a may control the electrical connection of the 2bth transistor T2b and the output terminal OUT of the scan signal according to the voltage of the QB node QB.

The 2bth transistor T2b may control the electrical connection of the input terminal of the first gate driving voltage VGH and the 2ath transistor T2a according to the voltage of the QB node QB. The CQB capacitor CQB may form a capacitance between the QB node QB and the input terminal of the first gate driving voltage VGH..

The third transistor T3 may control the electrical connection of the input terminal of the start signal VST and the Q2 node Q2 according to the first clock signal CLK1.

One side of the C_on capacitor C_on may be electrically connected to the input terminal of the first clock signal CLK1, and the other side of the C_on capacitor C_on may be electrically connected to the gate nodes of the fourth transistor T4 and the fifth transistor T5. The C_on capacitor C_on may be used as a stabilization capacitor. The capacitance of the C_on capacitor C_on may be smaller than the capacitance of the Q node capacitor CQ and the capacitance of the CQB capacitor CQB.

The fourth transistor T4 may control the electrical connection of the input terminal of the first gate driving voltage VGH and the gate node of the fifth transistor T5 according to the start signal VST.

The fifth transistor T5 may control the electrical connection of the input terminal of the first clock signal CLK1 and the QB node QB according to the voltage applied to the gate node.

The sixth transistor T6 may control the electrical connection of the first gate driving voltage VGH and the QB node QB according to the voltage of Q2 node Q2

The CQB capacitor CQB may be electrically connected between the QB node QB and the input terminal of the first gate driving voltage VGH, and may form a capacitance between the QB node QB and the input terminal of the first gate driving voltage VGH. The capacity of the CQB capacitor CQB may be larger than the capacity of the C_on capacitor C_on. The capacitance of the CQB capacitor CQB may be smaller than the capacitance of the Q node capacitor CQ.

The Q node charging transistor Ta may control the electrical connection of the Q2 node Q2 and the Q node Q according to the second gate driving voltage VGL.

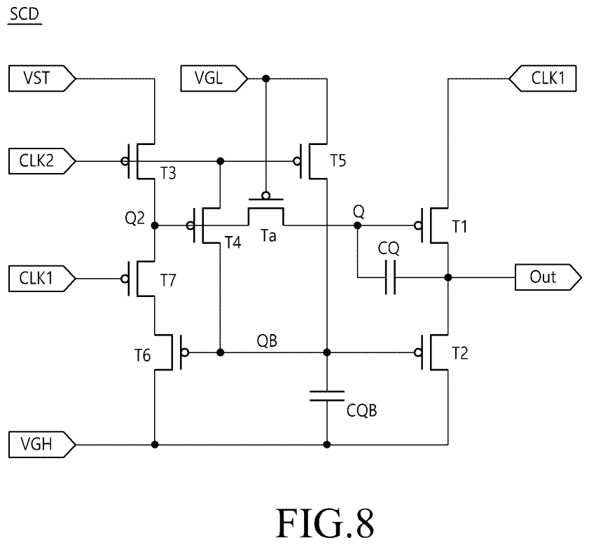

FIG. 8 is a view illustrating another scan driver SCD according to various embodiments of the disclosure.

The equivalent circuit diagram of the scan driver SCD illustrated in FIG. 8 may be illustrated as equivalent circuit diagram of the plurality of scan drivers SCD1-2, SCD2-2, SCD3-2, and SCD4-2 outputting the second scan signal SC2 and the plurality of scan drivers SCD1-3, SCD2-3, SCD3-3, and SCD4-3 outputting the third scan signal SC3.

The equivalent circuit diagrams of the scan driver SCD outputting the first scan signal SC1 and the scan driver SCD outputting the second scan signal SC2 may be different. The equivalent circuit diagrams of the scan driver SCD outputting the first scan signal SC1 and the scan driver SCD outputting the third scan signal SC3 may be different.

Referring to FIG. 8, a scan driver SCD may include a plurality of transistors T1, T2, T3, T4, T5, T6, T7, and Ta and at least one capacitor CQ and CQB.

The first transistor T1 may control the electrical connection of the input terminal of the first clock signal CLK1 and the output terminal OUT of the scan signal according to the voltage of the Q node Q.

The Q node capacitor CQ may be connected between the output terminal OUT of the scan signal and the Q node Q, and may form a capacitance between the output terminal OUT of the scan signal and the Q node Q. The capacitance of the Q node capacitor CQ may be smaller than the capacitance of the CQB capacitor CQB.

The second transistor T2 may control the electrical connection of the input terminal of the first gate driving voltage VGH and the output terminal OUT of the scan signal according to the voltage of the QB node QB.

The third transistor T3 may control the electrical connection of the input terminal of the start signal VST and the Q2 node Q2 according to the second clock signal CLK2.

The fourth transistor T4 may control the electrical connection of the input terminal of the second clock signal CLK2 and the QB node QB according to the voltage of the Q2 node Q2.

The fifth transistor T5 may control the electrical connection of the input terminal of the second gate driving voltage VGL and the QB node QB according to the second clock signal CLK2.

The sixth transistor T6 may control the electrical connection between the input terminal of the first gate driving voltage VGH and the seventh transistor T7 according to the voltage of the QB node QB.

The CQB capacitor CQB may be electrically connected between the QB node QB and the input terminal of the first gate driving voltage VGH, and may form a capacitance between the QB node QB and the input terminal of the first gate driving voltage VGH. The capacitance of the CQB capacitor CQB may be larger than the capacitance of the Q node capacitor CQ.

The Q node charging transistor Ta may control the electrical connection of the Q2 node Q2 and the Q node Q according to the second gate driving voltage VGL.

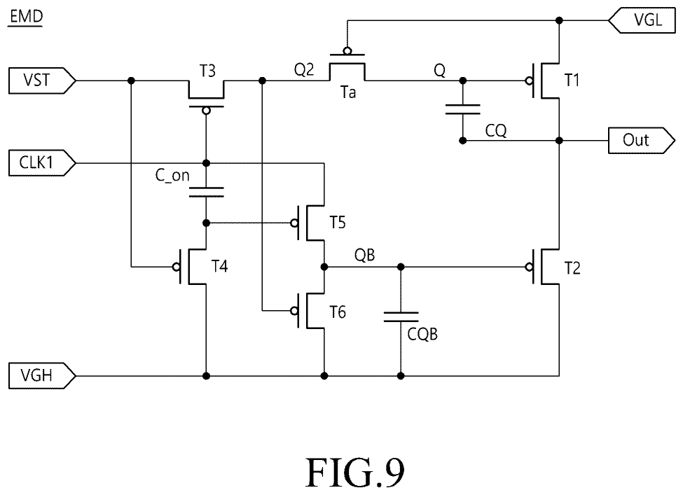

FIG. 9 is a view illustrating an emission driver EMD according to embodiments of the disclosure.

The equivalent circuit diagram of the light emitting driver EMD illustrated in FIG. 9 may be exemplified as an equivalent circuit diagram of a plurality of light emitting drivers EMD1 and EMD2 outputting the first emission control signal EM1 and the second emission control signal EM2.

Referring to FIG. 9, the light emitting driver EMD may include a plurality of transistors T1, T2, T3, T4, T5, T6, and Ta and at least one capacitor CQ, CQB, and C_on.

The first transistor T1 may control the electrical connection of the input terminal of the second gate driving voltage VGL and the output terminal OUT of the emission control signal according to the voltage of the Q node Q.

The Q node capacitor CQ may be connected between the output terminal OUT of the emission control signal and the Q node Q, and may form a capacitance between the output terminal OUT and the Q node Q of the emission control signal. The capacitance of the Q node capacitor CQ may be larger than the capacitance of the C_on capacitor C_on and the capacitance of the CQB capacitor CQB.

The second transistor T2 may control the electrical connection of the input terminal of the first gate driving voltage VGH and the output terminal OUT of the emission control signal according to the voltage of the QB node QB.

The third transistor T3 may control the electrical connection of the input terminal of the start signal VST and the Q2 node Q2 according to the first clock signal CLK1.

One side of the C_on capacitor C_on may be electrically connected to the input terminal of the first clock signal CLK1, and the other side of the C_on capacitor C_on may be electrically connected to the gate nodes of the fourth transistor T4 and the fifth transistor T5. The C_on capacitor C_on may be used as a stabilization capacitor. The capacitance of the C_on capacitor C_on may be smaller than the capacitance of the Q node capacitor CQ and the capacitance of the CQB capacitor CQB.

The fourth transistor T4 may control the electrical connection of the input terminal of the first gate driving voltage VGH and the gate node of the fifth transistor T5 according to the start signal VST.

The fifth transistor T5 may control the electrical connection of the input terminal of the first clock signal CLK1 and the QB node QB according to the voltage applied to the gate node.

The sixth transistor T6 may control the electrical connection of the first gate driving voltage VGH and the QB node QB according to the voltage of Q2 node Q2

The CQB capacitor CQB may be electrically connected between the QB node QB and the input terminal of the first gate driving voltage VGH, and may form a capacitance between the QB node QB and the input terminal of the first gate driving voltage VGH. The capacitance of the CQB capacitor CQB may be smaller than the capacitance of the Q node capacitor CQ. The capacitance of the CQB capacitor CQB may be smaller than that of the C_on capacitor C_on.

The Q node charging transistor Ta may control the electrical connection of the Q2 node Q2 and the Q node Q according to the second gate driving voltage VGL.

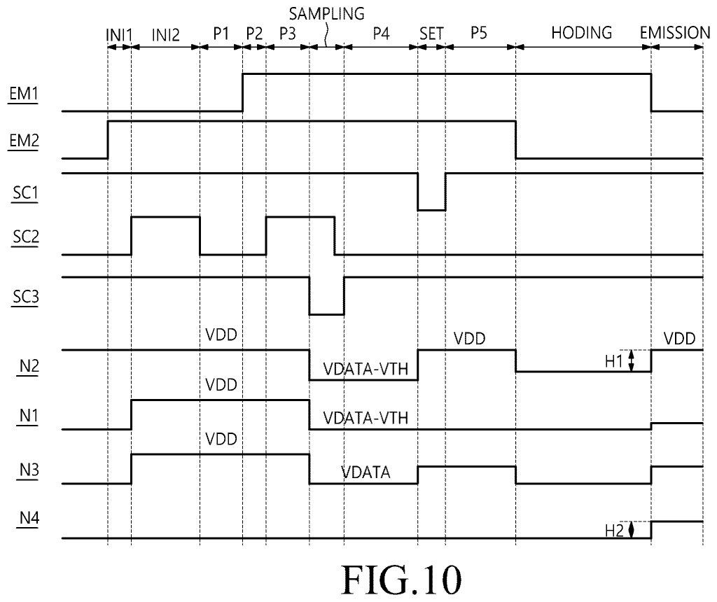

FIG. 10 is a timing diagram of a subpixel SP according to embodiments of the disclosure.

Referring to FIG. 10, the driving period of the subpixel SP includes a first initialization period INI1, a second initialization period INI2, a first driving period P1, a second driving period P2, a third driving period P3, a sampling period SAMPLING, a fourth driving period P4, a second node setting period SET, a holding period HOLDING, and an emission period EMISSION.

Within the first initialization period INI1, the first emission control signal EM1 may have a low-level voltage. The second emission control signal EM2 may have a high-level voltage. The first scan signal SC1 may have a high-level voltage. The second scan signal SC2 may have a low-level voltage. The third scan signal SC3 may have a high-level voltage.

Within the first initialization period INI1, the voltage of the first node N1 may be between the initialization voltage VINI and the data voltage VDATA. The voltage of the second node N2 may be a driving voltage VDD. The voltage of the third node N3 may be a voltage between the initialization voltage VINI and the data voltage VDATA. The voltage of the fourth node N4 may be the initialization voltage VINI.

The first emission control transistor EMT1 may be turned on as the first emission control signal EM1 of the low level is input to the gate node. Accordingly, the driving voltage VDD may be input to the second node N2.

The second emission control transistor EMT2 may be turned off as the second emission control signal EM2 of the high level is input to the gate node.

As the first scan signal SC1 of the high level is input to the gate node, the first scan transistor SCT1 may be turned off.

As the second scan signal SC2 of the low level is input to the gate node, the second scan transistor SCT2 may be turned off.

As the third scan signal SC3 of the high level is input to the gate node, the third scan transistor SCT3 may be turned off.

The initialization transistor INIT may be turned on as the second emission control signal EM2 of the high level is input to the gate node. Accordingly, the initialization voltage INI may be input to the other side of the storage capacitor CST and the fourth node N4.

Within the second initialization period INI2, the first emission control signal EM1 may have a low-level voltage. The second emission control signal EM2 may have a high-level voltage. The first scan signal SC1 may have a high-level voltage. The second scan signal SC2 may transition from a low-level voltage to a high-level voltage. The third scan signal SC3 may have a high-level voltage. Within the second initialization period INI2, the voltage of the first node N1 may be a driving voltage VDD. The voltage of the second node N2 may be a driving voltage VDD. The voltage of the third node N3 may be a driving voltage VDD. The voltage of the fourth node N4 may be the initialization voltage VINI.

Accordingly, as the second scan signal SC2 of the high level is input to the gate node, the second scan transistor SCT2 may be turned on. Accordingly, the driving voltage VDD input to the second node N2 may be input to the first node N1.

As the voltage of the first node N1 is the driving voltage VDD, the driving transistor DT may be turned on. As the driving transistor DT is turned on, the third node N3 may receive the driving voltage VDD. Within the first driving period P1, the first emission control signal EM1 may have a low-level voltage. The second emission control signal EM2 may have a high-level voltage. The first scan signal SC1 may have a high-level voltage. The second scan signal SC2 may transition from a high-level voltage to a low-level voltage. The third scan signal SC3 may have a high-level voltage.

Within the first driving period P1, the voltage of the first node N1 may be a driving voltage VDD. The voltage of the second node N2 may be a driving voltage VDD. The voltage of the third node N3 may be a driving voltage VDD. The voltage of the fourth node N4 may be the initialization voltage VINI.

Accordingly, as the second scan signal SC2 of the low level is input to the gate node, the second scan transistor SCT2 may be turned off. Accordingly, the first node N1 may be in a floating state (e.g., a “floating state” means a condition in which no continuous current path exists between a node and any external voltage source or ground, and the node retains its voltage based on residual charge without active driving.). Within the second driving period P2, the first emission control signal EM1 may transition from a low-level voltage to a high-level voltage. The second emission control signal EM2 may have a high-level voltage. The first scan signal SC1 may have a high-level voltage. The second scan signal SC2 may have a low-level voltage. The third scan signal SC3 may have a high-level voltage.

Within the second driving period P2, the voltage of the first node N1 may be a driving voltage VDD. The voltage of the second node N2 may be a driving voltage VDD. The voltage of the third node N3 may be a driving voltage VDD. The voltage of the fourth node N4 may be the initialization voltage VINI.

Accordingly, as the first emission control signal EMT1 of the high level is input to the gate node, the first emission control transistor EMT1 may be turned off. Accordingly, the second node N2 may be in a floating state. Within the third driving period P3, the first emission control signal EM1 may have a high-level voltage. The second emission control signal EM2 may have a high-level voltage. The first scan signal SC1 may have a high-level voltage. The second scan signal SC2 may transition from a low-level voltage to a high-level voltage. The third scan signal SC3 may have a high-level voltage.

Within the third driving period P3, the voltage of the first node N1 may be a driving voltage VDD. The voltage of the second node N2 may be a driving voltage VDD. The voltage of the third node N3 may be a driving voltage VDD. The voltage of the fourth node N4 may be the initialization voltage VINI.

Accordingly, as the second scan signal SC2 of the high level is input to the gate node, the second scan transistor SCT2 may be turned on. Within the sampling period SAMPLING, the first emission control signal EM1 may have a high-level voltage. The second emission control signal EM2 may have a high-level voltage. The first scan signal SC1 may have a high-level voltage. The second scan signal SC2 may have a high-level voltage. The third scan signal SC3 may transition from a high-level voltage to a low-level voltage.

Within the sampling period SAMPLING, the voltage of the first node N1 may be a voltage obtained by subtracting the threshold voltage VTH of the driving transistor DT from the data voltage VDATA. The voltage of the second node N2 may be a voltage obtained by subtracting the threshold voltage VTH of the driving transistor DT from the data voltage VDATA. The voltage of the third node N3 may be a data voltage VDATA. The voltage of the fourth node N4 may be the initialization voltage VINI.

Accordingly, as the third scan signal SC3 of the low level is input to the gate node, the third scan transistor SCT3 may be turned on. Accordingly, the third node N3 may receive the data voltage VDATA.

The data voltage VDATA may be input to the second node N2 while the driving transistor DT is turned on. In this case, the voltage of the second node N2 may be a voltage obtained by subtracting the threshold voltage VTH of the driving transistor DT from the data voltage VDATA.

The voltage of the second node N2 may be input to the first node N1 as the second scan transistor SCT2 is turned on. Further, the voltage of the first node N1 may be input to one side of the storage capacitor CST. Within the fourth driving period P4, the first emission control signal EM1 may have a high-level voltage. The second emission control signal EM2 may have a high-level voltage. The first scan signal SC1 may have a high-level voltage. The second scan signal SC2 may transition from a high-level voltage to a low-level voltage. The third scan signal SC3 may transition from a low-level voltage to a high-level voltage.

Within the fourth driving period P4, the voltage of the first node N1 may be a voltage obtained by subtracting the threshold voltage VTH of the driving transistor DT from the data voltage VDATA. The voltage of the second node N2 may be a voltage obtained by subtracting the threshold voltage VTH of the driving transistor DT from the data voltage VDATA. The voltage of the third node N3 may be a data voltage VDATA. The voltage of the fourth node N4 may be the initialization voltage VINI.

Accordingly, as the second scan signal SC2 of the low level is input to the gate node, the second scan transistor SCT2 may be turned off.

As the third scan signal SC3 of the high level is input to the gate node, the third scan transistor SCT3 may be turned off. Accordingly, the third node N3 may be in a floating state. Within the second node setting period SET, the first emission control signal EM1 may have a high-level voltage. The second emission control signal EM2 may have a high-level voltage. The first scan signal SC1 may transition from a high-level voltage to a low-level voltage. The second scan signal SC2 may have a low-level voltage. The third scan signal SC3 may have a high-level voltage.

Within the second node setting period SET, the voltage of the first node N1 may be a voltage obtained by subtracting the threshold voltage VTH of the driving transistor DT from the data voltage VDATA. The voltage of the second node N2 may be a driving voltage VDD. The voltage of the third node N3 may be a voltage between the data voltage VDATA and the driving voltage VDD. The voltage of the fourth node N4 may be the initialization voltage VINI.

As the first scan signal SC1 of the low level is input to the gate node, the first scan transistor SCT1 may be turned on. Accordingly, the driving voltage VDD may be input to the second node N2. Accordingly, the voltage of the third node N3 may also be increased by capacitive coupling. When the driving voltage VDD is input to the second node N2 during the second node setting period SET, voltage fluctuations at the second node N2 during the emission period EMISSION may be reduced or minimized.

Further, voltage fluctuations at the fourth node N4 due to capacitive coupling may be reduced or minimized during the emission period EMISSION. As the voltage fluctuations at the fourth node N4 are reduced or minimized, the fourth node N4 may not be at the turn-on voltage of the light emitting element ED while the voltage difference (i.e., the gate-source voltage) between the first node N1 and the third node N3 is lower than the threshold voltage VTH of the driving transistor DT. As the fourth node N4 is not at the turn-on voltage of the light emitting element ED, the light emitting element ED may not be turned on in an unintended period. Within the fifth driving period P5, the first emission control signal EM1 may have a high-level voltage. The second emission control signal EM2 may have a high-level voltage. The first scan signal SC1 may transition from a low-level voltage to a high-level voltage. The second scan signal SC2 may have a low-level voltage. The third scan signal SC3 may have a high-level voltage.

Within the fifth driving period P5, the voltage of the first node N1 may be a voltage obtained by subtracting the threshold voltage VTH of the driving transistor DT from the data voltage VDATA. The voltage of the second node N2 may be a driving voltage VDD. The voltage of the third node N3 may be a voltage between the data voltage VDATA and the driving voltage VDD. The voltage of the fourth node N4 may be the initialization voltage VINI.

Accordingly, as the first scan signal SC1 of the high level is input to the gate node, the first scan transistor SCT1 may be turned off. The second node N2 may be in a floating state. Within the holding period HOLDING, the first emission control signal EM1 may have a high-level voltage. The second emission control signal EM2 may transition from a high-level voltage to a low-level voltage. The first scan signal SC1 may have a high-level voltage. The second scan signal SC2 may have a low-level voltage. The third scan signal SC3 may have a high-level voltage.

Within the holding period HOLDING, the voltage of the first node N1 may be a voltage obtained by subtracting the threshold voltage VTH of the driving transistor DT from the data voltage VDATA. The voltage of the second node N2 may be a voltage between the driving voltage VDD and a voltage obtained by subtracting the threshold voltage VTH from the data voltage VDATA. The voltage of the third node N3 may be a data voltage VDATA or a voltage between the data voltage VDATA and the driving voltage VDD. The voltage of the fourth node N4 may be the initialization voltage VINI.

Accordingly, the second emission control transistor EMT2 may be turned on as the low-level second emission control signal EM2 is input to the gate node. When the second emission control transistor EMT2 is turned on, the third node N3 and the fourth node N4 may be electrically connected to each other. As the third node N3 and the fourth node N4 are electrically connected to each other, the voltage of the third node N3 and the voltage of the fourth node N4 may be the same. The voltage of the third node N3 and the voltage of the fourth node N4 may be voltages between the initialization voltage VINI and the data voltage VDATA.

The initialization transistor INIT may be turned off as the second emission control signal EM2 of the low level is input to the gate node. Accordingly, the third node N3 and the fourth node N4 may be in a floating state.

Within the emission period EMISSION, the first emission control signal EM1 may transition from a high-level voltage to a low-level voltage. The second emission control signal EM2 may have a low-level voltage. The first scan signal SC1 may have a high-level voltage. The second scan signal SC2 may have a low-level voltage. The third scan signal SC3 may have a high-level voltage.

Accordingly, the first emission control transistor EMT1 may be turned on as the first emission control signal EM1 of the low level is input to the gate node. Accordingly, the driving voltage VDD may be input to the second node N2. As the driving voltage VDD is input to the second node N2 within the second node setting period SET, the amount of changes in the voltage of the second node N2 during the emission period EMISSION may be reduced or minimized.

The second emission control transistor EMT2 may be turned on as the second emission control signal EM2 of the low level is input to the gate node. Accordingly, the third node N3 and the fourth node N4 may be electrically connected to each other. As the third node N3 and the fourth node N4 are electrically connected to each other, the voltage of the third node N3 and the voltage of the fourth node N4 may be the same. The voltage of the third node N3 and the voltage of the fourth node N4 may be voltages between the initialization voltage VINI and the data voltage VDATA.

As the first scan signal SC1 of the high level is input to the gate node, the first scan transistor SCT1 may be turned off.

As the second scan signal SC2 of the low level is input to the gate node, the second scan transistor SCT2 may be turned off. The first node N1 may be in a floating state. As the first node N1 is in a floating state, the voltage may increase.

As the third scan signal SC3 of the high level is input to the gate node, the third scan transistor SCT3 may be turned off. Accordingly, the third node N3 may be in a floating state. As the third node N3 is in a floating state, the voltage may increase.

As the voltages of the first node N1 and the third node N3 increase, when the voltage difference between the voltages of the first node N1 and the third node N3 exceeds the threshold voltage VTH of the driving transistor DT, the driving transistor DT may be turned on and a current may flow to the light emitting element ED. As a current flows to the light emitting element ED, the light emitting element ED may emit light.

The initialization transistor INIT may be turned off as the second emission control signal EM2 of the low level is input to the gate node.

Within the emission period EMISSON, the voltage of the first node N1 may increase from a voltage obtained by subtracting the threshold voltage VTH of the driving transistor DT from the data voltage VDATA. The voltage of the second node N2 may increase to the driving voltage VDD. When the voltage of the second node N2 is increased, the voltage of the third node N3 may be instantaneously increased by capacitive coupling. When the voltage of the second node N2 is increased, the voltage of the fourth node N4 may be instantaneously increased by capacitive coupling. The first rising width H1 of the voltage of the second node N2 and the second rising width H2 of the voltage of the fourth node N4 may be proportional to each other.

As the voltage of the second node N2 before the emission period EMISSION is changed to the driving voltage VDD in the second node setting period SET, the first rising width H1 of the second node N2 may decrease in the emission period EMISSION. Accordingly, the second rising width H2 of the voltage of the fourth node N4 may also be decreased.

As the second rising width H2 decreases, an unintended turn-on of the light emitting element ED due to a potential difference between the voltage of the fourth node N4 and the base voltage VSS does not occur, and the light emitting element ED may be in a turn-off state while the difference voltage between the first node N1 and the third node N3 is lower than the threshold voltage VTH of the driving transistor DT.

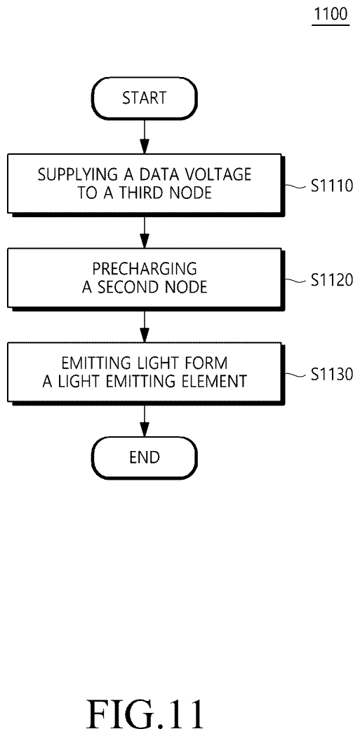

FIG. 11 is a flow chart of a method of operating a display device. In one embodiment, a method 1100 of operating a display device comprising a plurality of subpixels may include supplying a data voltage to a third node of a driving transistor included in a first subpixel among the plurality of subpixels (at S1110). The first subpixel in the disclosure may be one or more subpixels among the plurality of subpixels, or all of the subpixels among the plurality of subpixels. The driving transistor may be configured to control a connection between a second node and the third node according to a signal input to a first node. After the data voltage is supplied to the third node, a driving voltage may be precharged to the second node by selectively turning on either a first emission control transistor or a first scan transistor (at S1120). The precharging of the second node occurs prior to light emission from a light emitting element electrically connected to the driving transistor (at S1130), allowing the second node to stabilize at an appropriate potential necessary for reliable emission control.

In some embodiments, after the data voltage is supplied to the third node N3, the first node N1 and the third node N3 may be electrically isolated (i.e., placed in a floating state) before light emission begins. This isolation helps maintain the stored data voltage at the third node N3 and the threshold-related voltage at the first node N1, minimizing leakage current and preserving accurate driving conditions.

During precharging, capacitive coupling between the second node N2 and the third node N3 may increase the voltage of the third node N3 without requiring a direct electrical connection. As the voltage of the second node N2 increases due to the driving voltage input, the voltage of the third node N3 correspondingly rises via capacitive coupling, which in turn raises the voltage of a fourth node N4 connected to a pixel electrode PE of the light emitting element ED. The fourth node N4 may also remain electrically isolated from the driving voltage during the precharging operation, ensuring controlled voltage buildup through capacitive effects.

In some embodiments, the capacitive coupling between the second node and the third node may be achieved through an overlap or close proximity of conductive patterns disposed on different layers of the display device. This overlap structure enables efficient capacitive transmission of voltage changes during the precharge period. By relying on capacitive coupling instead of direct voltage driving of the third node, the method minimizes complexity and improves the stability of the voltage conditions before light emission, thereby enhancing the display quality and operational reliability.

A display device according to further embodiments of the disclosure may be described as follows.

A display device may comprise a display area where a plurality of subpixels are positioned and an image is displayed, and a non-display area outside the display area.

A first subpixel among the plurality of subpixels may include a light emitting element including a common electrode, an intermediate layer, and a pixel electrode, a driving transistor controlling a connection of a second node and a third node according to a signal input to a first node, a first driving voltage line and a second driving voltage line to which a driving voltage may be input, a first emission control transistor connected between the second node and the first driving voltage line and controlled by a first emission control signal, and a first scan transistor connected between the second node and the second driving voltage line and controlled by a first scan signal.

The driving voltage may be input to the second node while the first emission control transistor is turned on according to the first emission control signal or the first scan transistor is turned on according to the first scan signal.

The first subpixel may include a second scan transistor controlling a connection between the first node and the second node according to a second scan signal, a third scan transistor controlling a connection of the third node and a data line to which a data voltage may be input according to a third scan signal, a second emission control transistor controlling a connection of the third node and a fourth node connected with the pixel electrode according to a second emission control signal, a storage capacitor electrically connected between the first node and the fourth node, and an initialization transistor controlling a connection of an initialization voltage line to which an initialization voltage may be input and the fourth node according to the second emission control signal.

The light emitting element may not emit light by a voltage of the fourth node while a difference between a voltage of the first node and a voltage of the third node is lower than a threshold voltage of the driving transistor.

The driving transistor, the second scan transistor, and the initialization transistor may be oxide semiconductor transistors, and the first emission control transistor, the first scan transistor, the second emission control transistor, and the third scan transistor may be low temperature polycrystalline silicon (LTPS) transistors.

Before the light emitting element emits light as the first emission control transistor and the second emission control transistor are turned on, the second node may receive the driving voltage as the first scan transistor is turned on.

While the first emission control transistor, the second emission control transistor, and the first scan transistor are turned off, and the second scan transistor and the third scan transistor are turned on, the data voltage may be supplied to the third node, and a voltage obtained by subtracting a threshold voltage of the driving transistor from the data voltage may be supplied to the first node and the second node.

While the first emission control transistor and the second emission control transistor are turned on, the driving voltage is supplied to the second node so that, as a voltage of the second node increases, a voltage of the third node may increase and, as a voltage of the third node increases, a voltage of the fourth node may increase.

While a difference between a voltage of the first node and the voltage of the third node is lower than a threshold voltage of the driving transistor, the voltage of the fourth node may be lower than a voltage for turning on the light emitting element.

A display device may comprise a substrate, a first insulation layer positioned on the substrate, a shield pattern positioned on the first insulation layer, a second insulation layer positioned on the first insulation layer, a third insulation layer positioned on the second insulation layer, a first electrode and a second electrode of a driving transistor positioned on the third insulation layer, a drain node positioned on the second insulation layer, contacting the first electrode, and overlapping the shield pattern, a source node positioned on the second insulation layer, contacting a second electrode contacting the shield pattern, and overlapping the shield pattern, and a light emitting element including a pixel electrode contacting the second electrode, an intermediate layer disposed on the pixel electrode, and a common electrode disposed on the intermediate layer.

As a voltage input to the drain node increases, a voltage of the source node may increase and, as the voltage of the source node increases, a voltage of the pixel electrode may increase.

After a data voltage is applied to the source node, and before the intermediate layer emits light, a common voltage may be applied to the drain node. In some embodiments, the common voltage applied to the drain node prior to light emission may be lower than the driving voltage supplied during the light emission period. Applying a lower common voltage enables stabilization of node voltages without prematurely turning on the light emitting element.

The display device may further comprise an active layer disposed between the drain node and the source node.

The active layer may include an oxide semiconductor material.

An overlap area between the shield pattern and the drain node and an overlap area between the shield pattern and the source node are selectively adjusted based on desired capacitive characteristics for the drain node and the source node, respectively.

A subpixel may comprise a light emitting element including a common electrode, an intermediate layer, and a pixel electrode, a driving transistor controlling a connection of a second node and a third node according to a signal input to a first node, a first driving voltage line and a second driving voltage line to which a driving voltage may be input, a first emission control transistor connected between the second node and the first driving voltage line and controlled by a first emission control signal, and a first scan transistor connected between the second node and the second driving voltage line and controlled by a first scan signal.

In the subpixel, after a data voltage is applied to the third node, and before the light emitting element emits light, the second node receives the driving voltage as the first scan transistor is turned on.

The first subpixel may include a second scan transistor controlling a connection between the first node and the second node according to a second scan signal, a third scan transistor controlling a connection of the third node and a data line to which a data voltage may be input according to a third scan signal, a second emission control transistor controlling a connection of the third node and a fourth node connected with a second electrode of the light emitting element according to a second emission control signal, a storage capacitor electrically connected between the first node and the fourth node, and an initialization transistor controlling a connection of an initialization voltage line to which an initialization voltage may be input and the fourth node according to the second emission control signal.

The light emitting element may not emit light by a voltage of the fourth node while a difference between a voltage of the first node and a voltage of the third node is lower than a threshold voltage of the driving transistor.

The driving transistor, the second scan transistor, and the initialization transistor may be oxide semiconductor transistors, and the first emission control transistor, the first scan transistor, the second emission control transistor, and the third scan transistor may be low temperature polycrystalline silicon (LTPS) transistors.

While the first emission control transistor, the second emission control transistor, and the first scan transistor are turned off, and the second scan transistor and the third scan transistor are turned on, the data voltage may be supplied to the third node, and a voltage obtained by subtracting a threshold voltage of the driving transistor from the data voltage may be supplied to the first node and the second node.

While the first emission control transistor and the second emission control transistor are turned on, the driving voltage may be supplied to the second node so that, as a voltage of the second node increases, a voltage of the third node may increase and, as a voltage of the third node increases, a voltage of the fourth node may increase. While a difference between a voltage of the first node and the voltage of the third node is lower than a threshold voltage of the driving transistor, the voltage of the fourth node may be lower than a voltage for turning on the light emitting element.

After a data voltage is applied to the third node, and before the light emitting element emits light, while the second node receives the driving voltage as the first scan transistor is turned on, the driving voltage may not be input to the first node and the third node as the second scan transistor and the driving transistor are turned off.

After a data voltage is applied to the third node, and before the light emitting element emits light, while the second node receives the driving voltage as the first scan transistor is turned on, the first node and the third node may be in a floating state.

As used herein, a “floating state” refers to a condition in which a node, such as the first node or the third node, is electrically isolated from any voltage supply line, ground, or active signal path. In a floating state, no transistor is turned on to actively maintain or drive the node to a predetermined voltage, and the node maintains its voltage level based on previously stored charge. For example, after a data voltage is written to the third node and before light emission by the light emitting element begins, the first node and the third node may enter a floating state by turning off associated scan transistors and the driving transistor. The floating state suppresses leakage current paths, preserves the voltage difference required for stable operation of the driving transistor, and prevents unintended light emission or image sticking prior to the emission period.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display area where a plurality of subpixels is positioned and configured to display an image; and
a non-display area adjacent to the display area, wherein a first subpixel among the plurality of subpixels includes:
a light emitting element including a common electrode, an intermediate layer, and a pixel electrode;
a driving transistor configured to control a connection of a second node and a third node according to a signal input to a first node;
a first driving voltage line and a second driving voltage line to which a driving voltage is input;
a first emission control transistor connected between the second node and the first driving voltage line and controlled by a first emission control signal; and
a first scan transistor connected between the second node and the second driving voltage line and controlled by a first scan signal, and
wherein the driving voltage is input to the second node while the first emission control transistor is turned on according to the first emission control signal or the first scan transistor is turned on according to the first scan signal.

2. The display device of claim 1, wherein the first subpixel includes:
a second scan transistor configured to control a connection between the first node and the second node according to a second scan signal; and
a third scan transistor configured to control a connection of the third node and a data line to which a data voltage is input according to a third scan signal.

3. The display device of claim 2, wherein the first subpixel further includes:
a second emission control transistor configured to control a connection of the third node and a fourth node connected with the pixel electrode according to a second emission control signal;
a storage capacitor electrically connected between the first node and the fourth node; and
an initialization transistor configured to control a connection of an initialization voltage line to which an initialization voltage is input and the fourth node according to the second emission control signal.

4. The display device of claim 3, wherein the light emitting element does not emit light by a voltage of the fourth node while a difference between a voltage of the first node and a voltage of the third node is lower than a threshold voltage of the driving transistor.

5. The display device of claim 3, wherein the driving transistor, the second scan transistor, and the initialization transistor are oxide semiconductor transistors, and the first emission control transistor, the first scan transistor, the second emission control transistor, and the third scan transistor are low temperature polycrystalline silicon, LTPS, transistors.

6. The display device of claim 3, wherein before the light emitting element emits light as the first emission control transistor and the second emission control transistor are turned on, the second node receives the driving voltage as the first scan transistor is turned on.

7. The display device of claim 3, wherein while the first emission control transistor, the second emission control transistor, and the first scan transistor are turned off, and the second scan transistor and the third scan transistor are turned on, the data voltage is supplied to the third node, and a voltage obtained by subtracting a threshold voltage of the driving transistor from the data voltage is supplied to the first node and the second node.

8. The display device of claim 3, wherein while the first emission control transistor and the second emission control transistor are turned on, the driving voltage is supplied to the second node so that, as a voltage of the second node increases, a voltage of the third node increases and, as a voltage of the third node increases, a voltage of the fourth node increases, and
wherein while a difference between a voltage of the first node and the voltage of the third node is lower than a threshold voltage of the driving transistor, the voltage of the fourth node is lower than a voltage for turning on the light emitting element.

9. A display device, comprising:
a substrate;
a first insulation layer on the substrate;
a shield pattern on the first insulation layer;
a second insulation layer on the first insulation layer;
a third insulation layer on the second insulation layer;
a first electrode and a second electrode of a driving transistor on the third insulation layer;
a drain node on the second insulation layer, contacting the first electrode, and overlapping the shield pattern;
a source node on the second insulation layer, contacting a second electrode contacting the shield pattern, and overlapping the shield pattern; and
a light emitting element including a pixel electrode contacting the second electrode, an intermediate layer on the pixel electrode, and a common electrode on the intermediate layer,
wherein as a voltage input to the drain node increases, a voltage of the source node increases and, as the voltage of the source node increases, a voltage of the pixel electrode increases, and
wherein after a data voltage is applied to the source node, and before the intermediate layer emits light, a common voltage is applied to the drain node.

10. The display device of claim 9, further comprising an active layer between the drain node and the source node,
wherein the active layer includes an oxide semiconductor material.

11. The display device of claim 9, wherein an overlap area between the shield pattern and the source node is configured to enhance capacitive coupling relative to an overlap area with the drain node.

12. The display device of claim 9, wherein the common voltage applied to the drain node before light emission is lower than a driving voltage supplied during light emission.

13. A subpixel, comprising:
a light emitting element including a common electrode, an intermediate layer, and a pixel electrode;
a driving transistor configured to control a connection of a second node and a third node according to a signal input to a first node;
a first driving voltage line and a second driving voltage line to which a driving voltage is input;
a first emission control transistor connected between the second node and the first driving voltage line and controlled by a first emission control signal; and
a first scan transistor connected between the second node and the second driving voltage line and controlled by a first scan signal,
wherein after a data voltage is applied to the third node, and before the light emitting element emits light, the second node receives the driving voltage as the first scan transistor is turned on.

14. The subpixel of claim 13, further comprising:
a second scan transistor configured to control a connection between the first node and the second node according to a second scan signal;
a third scan transistor configured to control a connection of the third node and a data line to which a data voltage is input according to a third scan signal;
a second emission control transistor configured to control a connection of the third node and a fourth node connected with the pixel electrode of the light emitting element according to a second emission control signal;
a storage capacitor electrically connected between the first node and the fourth node; and
an initialization transistor configured to control a connection of an initialization voltage line to which an initialization voltage is input and the fourth node according to the second emission control signal.

15. The subpixel of claim 14, wherein the light emitting element does not emit light by a voltage of the fourth node while a difference between a voltage of the first node and a voltage of the third node is lower than a threshold voltage of the driving transistor.

16. The subpixel of claim 14, wherein the driving transistor, the second scan transistor, and the initialization transistor are oxide semiconductor transistors, and the first emission control transistor, the first scan transistor, the second emission control transistor, and the third scan transistor are low temperature polycrystalline silicon, LTPS, transistors.

17. The subpixel of claim 14, wherein while the first emission control transistor, the second emission control transistor, and the first scan transistor are turned off, and the second scan transistor and the third scan transistor are turned on, the data voltage is supplied to the third node, and a voltage obtained by subtracting a threshold voltage of the driving transistor from the data voltage is supplied to the first node and the second node.

18. The subpixel of claim 14, wherein while the first emission control transistor and the second emission control transistor are turned on, the driving voltage is supplied to the second node so that, as a voltage of the second node increases, a voltage of the third node increases and, as a voltage of the third node increases, a voltage of the fourth node increases, and
wherein while a difference between a voltage of the first node and the voltage of the third node is lower than a threshold voltage of the driving transistor, the voltage of the fourth node is lower than a voltage for turning on the light emitting element.

19. The subpixel of claim 14, wherein after a data voltage is applied to the third node, and before the light emitting element emits light, while the second node receives the driving voltage as the first scan transistor is turned on, the driving voltage is not input to the first node and the third node as the second scan transistor and the driving transistor are turned off.

20. The subpixel of claim 14, wherein after a data voltage is applied to the third node, and before the light emitting element emits light, while the second node receives the driving voltage as the first scan transistor is turned on, the first node and the third node are in a floating state.
